(19) United States
(12) Patent Application Publication
(10) Pub. No.: US 2009/0127565 A1
(43) Pub. Date: May 21, 2009

(54) P-n junctions on mosaic diamond substrates

(76) Inventor: Chien-Min Sung, Tansui (TW)

Correspondence Address: THORPE NORTH & WESTERN, LLP., P.O. Box 1219, SANDY, UT, 84091-1219, US

(21) Appl. No.: 11/712,231

(22) Filed: Feb. 27, 2007

Related U.S. Application Data
(63) Continuation-in-part of application No. 11/200,647, filed on Aug. 9, 2005.

(51) Int. Cl. H01L 29/15; C30B 1/00

(52) U.S. Cl. 257/77; 117/6; 257/E21.102

(57) ABSTRACT

The present invention provides methods of making and using semiconductive single crystal diamond bodies, including semiconductive diamond bodies made by such methods. In one aspect, a method of making a semiconductive single crystal diamond layer may include placing a plurality of diamond segments in close proximity under high pressure in association with a molten catalyst and a carbon source, where the diamond segments are arranged in a single crystal orientation. The plurality of diamond segments are then maintained under high pressure in the molten catalyst until the plurality of diamond segments have joined together with diamond to diamond bonds to form a substantially single crystal diamond body. Following creation of the single crystal diamond body, a homoepitaxial single crystal diamond layer may be deposited on the single crystal diamond body. A dopant may be introduced into the homoepitaxial single crystal diamond layer to form a semiconductive single crystal diamond layer.

### PRIORITY DATA

This application is a continuation-in-part of U.S. patent application Ser. No. 11/200,647, filed Aug. 9, 2005, which is incorporated herein by reference.

### FIELD OF THE INVENTION

The present invention relates generally to diamond p-n junctions and associated methods. Accordingly, the present invention involves the fields of chemistry, metallurgy, materials science, physics, and high pressure technology.

### BACKGROUND OF THE INVENTION

Diamond is an ideal material for many applications due to its extreme hardness, atomic density, and high thermal conductivity. As such, large diamond bodies would benefit numerous applications, including those involving tools, substrates, electronic components, etc. Diamond bodies comprised of essentially a single crystal orientation are highly sought after, particularly in association with semiconductors and heat spreaders.

As computers and other electronic devices become smaller and faster, the demands placed on semiconductor devices utilized therein increase geometrically. These increased demands can create numerous problems due to the accumulation of charge carriers, i.e. electrons and holes that are intrinsic to quantum fluctuation. Accumulation of the carriers creates noise, and tends to obscure electrical signals within the semiconductor device. This problem is compounded as the temperature of the device increases. Much of the carrier accumulation may be due to the intrinsically low bonding energy and the directional anisotropy of typical semiconductor crystal lattices. Another problem may be a further result of current semiconductor materials. These semiconductors tend to have a high leaking current and a low break down voltage. As the size of semiconductor transistors and other circuit elements decrease, coupled with the growing need to increase power and frequency, current leak and break down voltage also become critical.

As power and frequency requirements increase and the size of semiconductor components decreases, the search for materials to alleviate these problems becomes crucial to the progress of the semiconductor industry. One material that may be suitable for the next generation of semiconductor devices is diamond. The physical properties of diamond, such as its high thermal conductivity, low intrinsic carrier concentration, and high band gap make it a desirable material for use in many high-powered electronic devices.

Methods for creating diamond layers can include known processes such as chemical vapor deposition (CVD), physical vapor deposition (PVD), and growth in high pressure apparatuses. Various CVD techniques have been used in connection with depositing diamond or diamond-like materials onto a substrate. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, are well known to those skilled in the art.

Though single crystal diamond films can be grown using CVD processes, they are currently very expensive and slow to grow to a sufficient thickness to be useful as a diamond body or a diamond substrate. CVD deposited polycrystalline diamond (PCD) layers, on the other hand, can be grown to a sufficient thickness more rapidly and with less expense. Grain boundaries inherent to the PCD layer, however, will create dislocations in the crystal lattice of any material deposited thereon, thus precluding their use in those applications requiring high quality crystal lattices. PVD processes create similar grain boundary issues, and are thus not desirable for many applications.

Unfortunately, currently known high pressure crystal synthesis methods also have several drawbacks which limit their ability to produce large, high-quality crystal bodies. For example, isothermal processes are generally limited to production of smaller crystals useful as superabrasives in cutting, abrading, and polishing applications. Temperature gradient processes can be used to produce larger diamonds; however, production capacity and quality are limited. Several methods have been utilized in an attempt to overcome these limitations. Some methods incorporate multiple diamond seeds; however, a temperature gradient among the seeds prevents achieving optimal growth conditions at more than one seed. Some methods involve providing two or more temperature gradient reaction assemblies such as those described in U.S. Pat. No. 4,632,817. Unfortunately, high quality diamond is typically produced only in the lower portions of these reaction assemblies. Some of these methods involve adjusting the temperature gradient to compensate for some of these limitations. However, such methods cost additional expense and require control of variables in order to control growth rates and diamond quality simultaneously over different temperatures and growth materials.

Therefore, apparatuses and methods which overcome the above difficulties would be a significant advancement in the area of high pressure crystal growth, and continue to be sought.

### SUMMARY OF THE INVENTION

Accordingly, the present invention provides methods of making and using semiconductive single crystal diamond bodies, including semiconductive diamond bodies made by such methods. In one aspect, for example, a method of making a semiconductive single crystal diamond layer is provided. Such a method may include placing a plurality of diamond segments in close proximity under high pressure in association with a molten catalyst and a carbon source, where the diamond segments are arranged in a single crystal orientation. The plurality of diamond segments are then maintained under high pressure in the molten catalyst until the plurality of diamond segments have joined together with diamond to diamond bonds to form a substantially single crystal diamond body. Following creation of the single crystal diamond body, a homoepitaxial single crystal diamond layer may be deposited on the single crystal diamond body. A dopant may be introduced into the homoepitaxial single crystal diamond layer to form a semiconductive single crystal diamond layer.

The molten catalyst may include a metal catalyst selected from the group consisting of Cr, Mn, Fe, Co, Ni, and combinations and alloys thereof. In another aspect the molten catalyst may include an Fe—Ni alloy. In one aspect, the carbon source may include a material selected from the group consisting of graphite, diamond, diamond powder, nanodiamond, microdiamond, and combinations thereof. In another aspect, the carbon source may be graphite. In yet another aspect, the graphite may include a low resistivity graphite. In a further aspect, the carbon source can include diamond powder.

Various configurations of diamond segments are contemplated by the present invention. In one aspect, the plurality of diamond segments may be arranged into a pattern prior to being placed under high pressure in a molten catalyst. It may be desirable to affix the diamond segments to a substrate prior to being placed under high pressure in a molten catalyst. They may be affixed by electroplating to the substrate with, for example, Ni electroplating. In another aspect, the diamond segments may be affixed to the substrate by a CVD diamond film. Furthermore, in one aspect the diamond segments may have a cubic shape. In another aspect, the diamond segments may have a cubic shape that is obtained without post-growth processing.

Numerous doping methods are known for introducing a dopant into a layer. It should be noted that any doping method known is considered to be within the scope of the present invention. Additionally, the dopant may include numerous specific dopants, including, without limitation, N, P, As, Sb, Bi, B, Al, Ga, In, and combinations thereof. In one specific aspect, however, the dopant may include B. In another specific aspect, the dopant may include N. In yet another aspect, the dopant may include P.

The present invention also provides devices made by various methods according to aspects disclosed or suggested herein. In one aspect, for example, a semiconductive single crystal diamond device is provided. Such a device may include a single crystal diamond body made as has been described, a homoepitaxial single crystal diamond layer coated on the single crystal diamond body, and a dopant disposed within the homoepitaxial single crystal diamond layer to form a semiconductive single crystal diamond layer.

In another aspect, a semiconductor device is provided, including a single crystal diamond body made as described herein, a homoepitaxial single crystal diamond layer coated on the single crystal diamond body, a first dopant disposed within the homoepitaxial single crystal diamond layer to form a semiconductive single crystal diamond layer, the first dopant being either B or Al, a single crystal cubic boron nitride layer disposed adjacent to the homoepitaxial single crystal diamond layer, and a second dopant disposed within the cubic boron nitride layer to form a semiconductive single crystal cubic boron nitride layer, the second dopant being N, P, or As. In one specific aspect the first dopant may include B. In another aspect the second dopant may include N.

### BRIEF DESCRIPTION OF THE DRAWINGS

FIG. 1 is a photograph of diamond cubes grown under high pressure;

FIG. 2 is another photograph of diamond cubes grown under high pressure;

FIG. 3 is a perspective view of a diamond body in accordance with an embodiment of the present invention;

FIG. 4 is a perspective view of a diamond body in accordance with another embodiment of the present invention;

FIG. 5 is a perspective view of a diamond body in accordance with yet another embodiment of the present invention;

FIG. 6 is a cross-sectional view of a high pressure assembly in accordance with an embodiment of the present invention;

FIG. 7 is a cross-sectional view of a diamond semiconductor device in accordance with an embodiment of the present invention; and

FIG. 8 is a cross-sectional view of a diamond semiconductor device in accordance with an embodiment of the present invention.

The above figures are provided for illustrative purposes only. It should be noted that actual dimensions of layers and features may differ from those shown.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

The singular forms “a,” “an,” and “the” include plural referents unless the context clearly dictates otherwise. Thus, for example, reference to “a diamond segment” includes reference to one or more of such segments, and reference to “a high pressure apparatus” includes reference to one or more of such devices.

### DEFINITIONS

In describing and claiming the present invention, the following terminology will be used in accordance with the definitions set forth below.

As used herein, the term “one dimensional” refers to a diamond body made from diamond segments aligned in only one dimension. An example of a one dimensional diamond body is shown in FIG. 3.

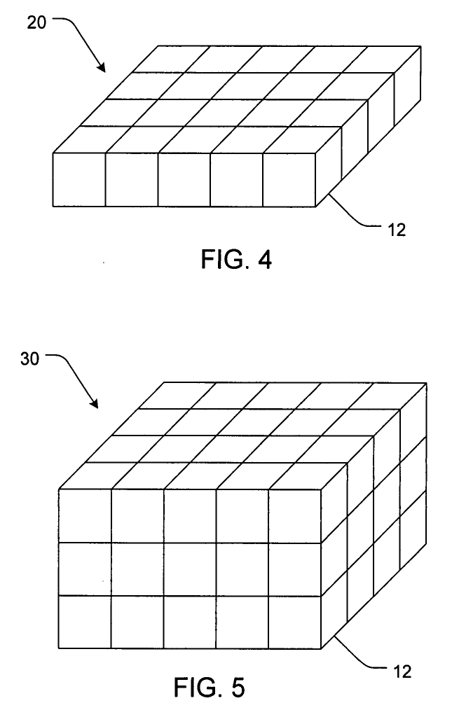

As used herein, the term “two dimensional” refers to a diamond body made from diamond segments aligned in only two dimensions. An example of a two dimensional diamond body is shown in FIG. 4.

As used herein, the term “three dimensional” refers to a diamond body made from diamond segments aligned in three dimensions. An example of a three dimensional diamond body is shown in FIG. 5.

The term “close proximity” as used herein refers to a distance between spatially arranged diamond segments which is close enough to allow adequate diamond deposition in the gap between the diamond segments to allow diamond to diamond bonds to form, but not so close so as to impede penetration of the carbon source or to cause premature closing of the gap.

As used herein, “high pressure assembly” refers to at least a portion of the high pressure apparatus in which conditions can be maintained at high pressure or ultrahigh pressure sufficient for growth of materials which are placed therein, e.g. usually the high pressure assembly can contain a carbon source, a catalyst material, and diamond seeds. These materials may be placed in the high pressure assembly at least partially surrounded by a pressure medium and/or gasket assembly. However, those skilled in the art will recognize that the high pressure assembly can be formed of almost any material which can then be subjected to high pressure for such purposes as chemical reactions, crystalline growth, high pressure property measurements, and the like. A wide variety of high pressure assemblies are known and can be used in the present invention. Such high pressure assemblies can also include inert gaskets, separators, or other materials which improve high-pressure/high-temperature conditions.

As used herein, “high pressure” refers to pressures above about 1 MPa and preferably above about 200 MPa.

As used herein, “ultrahigh pressure” refers to pressures from about 1 GPa to about 15 GPa, and preferably from about 4 GPa to about 7 GPa.

As used herein, “alloy” refers to a solid solution or liquid mixture of a metal with a second material, said second material may be a non-metal, such as carbon, a metal, or an alloy which enhances or improves the properties of the metal.

As used herein, “inclusion” refers to entrapment of non-diamond material within a growing crystal. Frequently, the inclusion is a catalyst metal enclosed within the crystal under rapid growth conditions. Alternatively, inclusions can be the result carbon deposits forming instead of diamond at the interface between a crystal growth surface of the diamond and the surrounding material. In general, inclusions are most often formed by the presence of substantial amounts of carbon at the growth surface of the diamond and/or inadequate control of temperature and pressure conditions during high-pressure/high-temperature growth.

As used herein, “thermal contact” refers to proximity between materials which allows for thermal transfer from one material to another. Therefore, thermal contact does not require that two materials be in direct physical contact. Materials can be chosen having various thermal conductivities so as to enhance or hinder thermal contact between materials as desired.

As used herein, “gem quality” refers to crystals having no visible irregularities (e.g., inclusions, defects, etc.) when observed by the unaided eye. Crystals grown in accordance with the present invention exhibit a comparable gem quality to that of natural crystals which are suitable for use in jewelry.

As used herein, “substrate” refers to a surface, to which various materials can be joined in forming a diamond device. The substrate may be any shape, thickness, or material, required in order to achieve a specific result, and includes but is not limited to metals, alloys, ceramics, and mixtures thereof. Further, in some aspects, the substrate, may be an existing semiconductor device or wafer, or may be a material which is capable of being joined to a suitable device.

As used herein, “metallic” refers to any type of material or compound wherein the majority portion of the material is a metal. Examples of various metals considered to be particularly useful in the practice of the present invention include, without limitation: aluminum, tungsten, molybdenum, tantalum, zirconium, vanadium, chromium, copper, and alloys thereof.

As used herein, the terms “diamond layer,” “sheet of diamond,” “diamond body,” etc., refer to any structure, regardless of shape, which contains diamond-containing materials. Thus, for example, a diamond film partially or entirely covering a surface is included within the meaning of these terms. Additionally, a layer of a material, such as metals, acrylics, or composites, having diamond particles disbursed therein is included in these terms.

As used herein, “diamond-containing materials” refer to any of a number of materials which include carbon atoms bonded with at least a portion of the carbons bonded in at least some sp bonding. Diamond-containing materials can include, but are not limited to, natural or synthetic diamond, polycrystalline diamond, diamond-like carbon, amorphous diamond, and the like.

As used herein, “grain boundaries” are boundaries in a crystalline lattice formed where adjacent seed crystals have grown together. An example includes polycrystalline diamond, where numerous seed crystals having grains of different orientations have grown together to form a heteroepitaxial layer.

As used herein, “crystal dislocations” or “dislocations” can be used interchangeably, and refer to any variation from essentially perfect order and/or symmetry in a crystalline lattice.

As used herein, “vapor deposited” refers to materials which are formed using vapor deposition techniques. “Vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically depositing diamond or other particles in a vapor form upon a surface. Various CVD techniques are well known in the art.

As used herein, “CVD passive material” refers to a material which does not allow substantial deposition of diamond or other materials using CVD methods directly to the material. One example of a CVD passive material with respect to deposition of diamond is copper. As such, during CVD processes carbon will not deposit on the copper but only on CVD active materials such as silicon, diamond, or other known materials. Thus, CVD passive materials can be “passive” with respect to some materials and not others. For example, a number of carbide formers can be successfully deposited onto copper.

As used herein, “physical vapor deposition,” or “PVD” refers to any method of physically depositing diamond particles in a vapor form upon a surface. Various PVD techniques are well known in the art.

As used herein, “disposed adjacent to” refers to two materials having adjacent surfaces where the materials are electrically coupled. In one aspect, electrical coupling may include physical contact. In another aspect, electrical coupling may include situations whereby a dielectric material may be disposed between the two materials. Examples of two layers being disposed adjacent to may include configurations where one layer is disposed on top of the other layer, where one layer is disposed next to or side by side with the other layer, where one layer is disposed within the other layer, etc.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

### THE INVENTION

Due to the ever decreasing size and increasing power requirements of semiconductor devices, efficient techniques for cooling have been continuously sought after. It is thought that diamond materials may be used to cool semiconductor devices due to their high thermal efficiency. In addition to purely thermal considerations, it is preferable that semiconductor materials have a single crystal orientation, and thus contain as few crystal lattice dislocations or grain boundaries as possible in order to maximize the efficiency of a semiconductor device.

Although single crystal diamond films can be CVD deposited with minimal grain boundaries, the cost is often prohibitive for depositing thick layers of diamond, particularly for use in the semiconductor arts where high quality semiconductor layers are vital. As such, it would be desirable to employ single crystal diamond bodies or layers that are less expensive to make and can be much thicker than conventional CVD diamond. Such single crystal diamond bodies can be used as a substrate for deposition of doped vapor-deposited diamond layers, thus creating thick diamond semiconducting materials. Because the underlying diamond body has a single crystal orientation, the CVD diamond layer will be deposited epitaxially, and thus will have few if any crystal dislocations. Such a device may function as a highly efficient diamond semiconductor.

Deposition of diamond material in the gaps between diamond segments can effectively produce a solid diamond body that is continuous in structure, and as such, is essentially a single diamond body. Such a diamond body may contain grain boundaries and crystal dislocations between the diamond segments, or it may be substantially lattice matched with few if any crystal dislocations. In those aspects where grain boundaries exist between diamond segments, an epitaxial CVD diamond layer may still be deposited due to the predominance of a single crystal orientation in majority of the diamond body surface, namely the orientation of the diamond segments themselves.

In one aspect of the present invention, a method of making a semiconductive single crystal diamond layer is provided. Such a method may include placing a plurality of diamond segments in close proximity under high pressure in association with a molten catalyst and a carbon source, the diamond segments being arranged in a single crystal orientation, and maintaining the plurality of diamond segments under high pressure in the molten catalyst until the plurality of diamond segments have joined together with diamond to diamond bonds to form a substantially single crystal diamond body. Following formation of the single crystal diamond body, a homoepitaxial single crystal diamond layer may be deposited on thereon, and a dopant may be introduced into the homoepitaxial single crystal diamond layer to form the semiconductive single crystal diamond layer. In many aspects the dopant would be introduced during the deposition of the homoepitaxial single crystal diamond layer. However, it should be understood that techniques whereby the dopant is introduced following the deposition of the diamond layer would also be included within the scope of the claims.

In a more specific aspect, a method of forming a substantially single crystal diamond body may further include arranging a plurality of diamond segments having a substantially uniform shape into a high pressure apparatus, the plurality of diamond segments being arranged in a predetermined pattern corresponding to a desired diamond body shape. A metal catalyst and a carbon source may be added to the high pressure apparatus, and a pressing force may then be applied to the high pressure apparatus which is sufficient to provide high pressures sufficient to alter the metal catalyst to a molten catalyst. The pressing force may be maintained for a time sufficient to join the plurality of diamond segments into a substantially single diamond body. Following formation of the diamond body, the doped homoepitaxial single crystal diamond layer may be deposited as described.

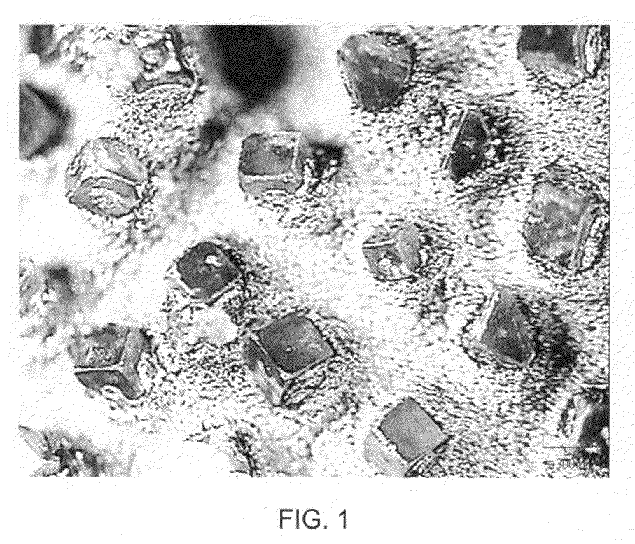

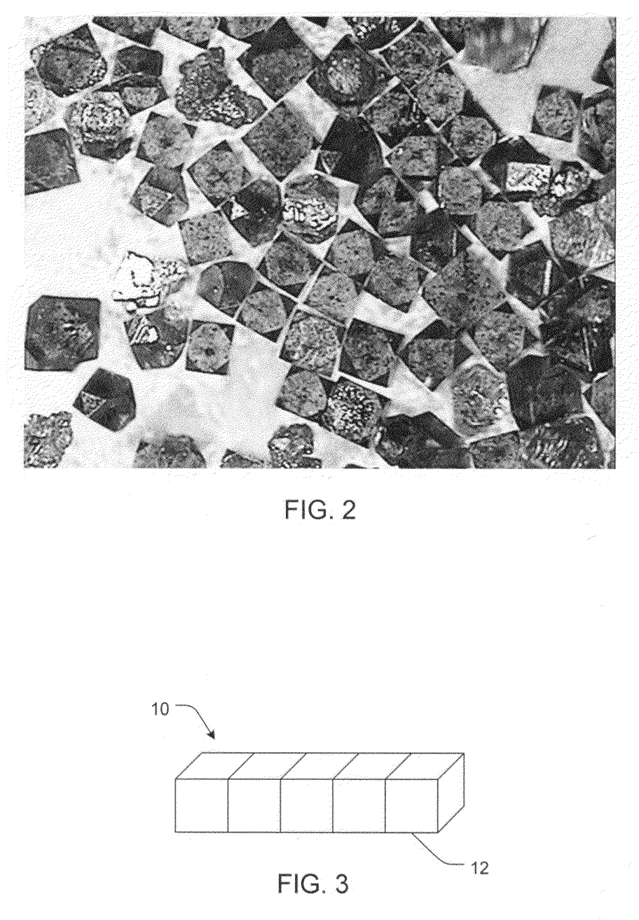

The diamond segments can be of any shape suitable for placement in close proximity. Many diamond shapes, however, have both cubic and octahedral faces exposed. This situation may complicate the formation of the diamond body, particularly in those aspects where lattice matching is desired, due to the misalignment of the crystal lattices between the cubic and octahedral faces as the diamond segments are arranged. As such, diamond segments that align with matching crystallographic faces may facilitate the formation of diamond to diamond bonds that exhibit improved lattice matching as compared to those with non-matching crystallographic faces. Such orientation may be facilitated by utilizing diamond segments have a cubic shape. In one aspect, diamond segments having cubic shapes are diamond cubes. Diamond cubes are useful in that they have the same cubic crystallographic face exposed on all sides, and thus the cubes line up together with aligned (100) faces. Thus the cubes will have aligned faces no matter how they orient while being arranged prior to the formation of a diamond body. This situation may facilitate improved lattice matching between diamond segments in the resulting diamond body. Processes and devices that may be utilized to grow high quality diamonds, including diamond cubes and other useful shapes, are described in U.S. Pat. No. 7,128,547, filed Jan. 13, 2004, and in U.S. patent application Ser. Nos. 10/926,576, filed Aug. 25, 2005, and 10/775,042, filed Feb. 06, 2004, each of which are incorporated by reference. FIGS. 1 and 2 show examples of diamond cubes grown by such a process. Advantageously, such processes grow diamond segments as diamond cubes, and thus require little or no post-growth processing. Post-growth processing may be defined as any process that alters the shape of a diamond segment after it has been grown, such as by polishing, cutting, grinding, etc.

Diamond segments can be positioned in a variety of configurations depending on the desired structure of the diamond body. As shown in FIG. 3, for example, diamond segments 12 can be aligned in a single row to form a one dimensional diamond body 10 such as a rod or a column. The overall shape and structure of the one dimensional diamond body 10 can be varied by utilizing various shapes of diamond segments 12, or by varying the alignment of the diamond segments 12 prior to joining. Diamond segments 12 can also be positioned into a two dimensional array in order to form a two dimensional sheet 20 or other layer structure, as shown in FIG. 4. In one aspect, the two dimensional sheet 20 can be formed by aligning diamond segments 12 into a two dimensional array and joining the entire array at the same time. In another aspect, a plurality of one dimensional structures 10 can be formed separately and subsequently aligned and joined into a two dimensional sheet 20. Regardless of the method of forming, a two dimensional diamond sheet 20 may be highly planar or it may have a curved or irregular surface depending on the intended application. For example, a two dimensional diamond sheet may be curved to form a diamond tube or other cylindrical body.

It is also contemplated, as shown in FIG. 5, that the diamond segments 12 can be positioned into a three dimensional array, and thus form a three dimensional diamond body 30 having a length, width, and height that are all greater than the length, width, and height of an individual diamond segment 12. The three dimensional diamond body 30 can be symmetrical or nonsymmetrical. It may be, for example, without limitation, a sheet having a height (or thickness) that is greater than the thickness of a single diamond segment, a rectangle, a sphere, a trapezoid, a pyramid, etc. It may also have an irregular surface to conform to an intended use. Any shape contemplated by one skilled in the art that can be constructed from diamond segments 12 is intended to be within the scope of the present invention. In one aspect, the three dimensional body 30 can be formed by aligning diamond segments 12 into a three dimensional array and joining the entire array at the same time. In another aspect, a plurality of two dimensional sheets 20, a plurality of one dimensional structures 10, or both can be formed separately and subsequently aligned and joined into a three dimensional body 30. Regardless of the method of forming, a three dimensional diamond body 20 may have highly planar surfaces or it may have at least one curved or irregular surface, depending on the intended application.

As such, in one aspect the plurality of diamond segments may be arranged into a pattern prior to being placed under high pressure in the molten catalyst. The segments can be arranged by any means known to one skilled in the art for placing small objects, including, without limitation, mechanical vibration, template transfer, etc. In the mechanical vibration method, the diamond segments may be placed in a shaker and vibrated until they align with each other on the shaker. If diamond cubes are utilized, a substantially single crystal diamond body can be grown due to the alignment of the exposed cubic faces of the diamonds. It may also be helpful to affix the diamond segments to a support substrate prior to their being placed under high pressure in the molten catalyst. Such attachment functions to immobilize the diamond segments in a desired position during movement and the high pressure growth process. In one aspect the diamond segments may be affixed to the support substrate by electroplating. One specific example of an electroplating process is nickel electroplating. Such processes are well known to those skilled in the art. The diamond segments can also be affixed to the substrate via a fixative. Any fixative, including adhesives, capable of substantially immobilizing the diamond segments to the support substrate that will not interfere with the diamond growth process is considered to be within the scope of the present invention. Specific examples may include epoxies, rubber cements, acrylics, etc.

The plurality of diamond segments may also be affixed at least partially together in order to eliminate movement after positioning. They can be affixed by any means known to one skilled in the art. In one example, the diamond segments 15 can be arranged and affixed at an exposed surface by a fixative. Alternatively, they can be affixed at an exposed surface by a vapor deposition process such as CVD or PVD deposition. In this aspect, a thin layer of a binding material can be deposited in order to immobilize the diamond segments into a single body. The binding material can be any material that can be vapor deposited, such as various metals, non-metals, and ceramics. In one aspect, the binding material can be a vapor deposited layer of diamond, including polycrystalline diamond (PCD). Following affixing, the diamond body can be turned over so the bound surface is proximal to a support substrate or positioning surface, and diamond growth can proceed on the now exposed surface. Various methods of positioning diamond segments and fixing them together and to a support substrate are described in U.S. Pat. No. 6,158,952, which is incorporated herein by reference.

The support substrate, when present, may be formed of any material known to one skilled in the art that can support the diamond segments under the conditions required for diamond growth and which does not interfere with such growth. In one aspect, the support substrate can allow raw material to diffuse thereinto. In another aspect, the support substrate may be metal catalyst. Non-limiting examples of material suitable for support substrates include graphite, NaCl, dolomite, talc, pyrophillite, metal oxides, and the like. The support substrate may be temporary, or it may be a permanent member of the diamond body.

In another aspect of the present invention, the diamond segments may be arranged in a refractory metal container. Materials suitable for the refractory metal container include, without limitation, tantalum, titanium zirconium, molybdenum, tungsten, etc. In this case, however, metal catalyst needs to be added to the refractory metal container along with the carbon source. Gasket or pressure medium materials outside the container may include, without limitation, sodium chloride, pyrophillite, talc, dolomite, hexagonal boron nitride, graphite, etc.

Various high pressure methods of generating diamond growth are known to those of ordinary skill in the art, and all are considered to be within the scope of the present invention. Typically, either isothermal methods or temperature gradient methods are used to synthesize diamond. Each method takes advantage of the solubility of carbon under various conditions, e.g., temperature, pressure, and concentrations of materials. In one aspect, an isothermal method involves the use of a carbon source material and a metal catalyst. The carbon source may be graphite or other forms of carbon material as described herein. Under high pressures and high temperatures, graphite is much more soluble in a molten catalyst than diamond. Therefore, graphite tends to dissolve or disperse into the molten catalyst, or create a colloidal suspension therewith, up to a saturation point. Excess carbon can then precipitate out as diamond along the gaps between the diamond segments. Typically, the growth surface of a diamond segment can be covered by a thin envelope of the molten catalyst. In this case, the carbon can dissolve into and diffuse across the molten catalyst envelope toward the diamond segment.

In another aspect, a temperature gradient method involves maintaining a temperature gradient between the carbon source and the diamond segments which are separated by a relatively thick layer of molten catalyst. The carbon source is kept at a relatively higher temperature than the gaps between the diamond segments. As such, the carbon is more soluble in the hotter regions. The carbon may then diffuse toward the cooler regions along the gaps between the diamond segments. The solubility of carbon is reduced in the cooler regions, thus allowing carbon to precipitate as diamond and thus seal the gaps. Typically, the molten catalyst layer is relatively thick in order to maintain a sufficient temperature gradient, e.g., 20° C. to 50° C.

As the gaps between the diamond segments are joined by diamond to diamond bonds, metal from the molten catalyst may become trapped in the grain boundary. This may not be problematic depending on the intended use of the resulting diamond body. For example, if the diamond body is to be utilized as a substrate for further epitaxial growth of a single crystal layer such as CVD deposited diamond, metal inclusions in the grain boundary may not affect the epitaxial growth of the CVD diamond layer. Such a single crystal layer can be deposited in situ during the formation of the diamond body, or following formation of the diamond body by means of various CVD processes. Similarly, heat spreaders, gemstones, tools, etc., may often not be affected by metal trapped in the grain boundary.

Other intended uses for the resulting diamond body, however, may be compromised by significant amounts of metal in the grain boundary. In these cases, the amount of metal inclusions can be minimized or eliminated by slowing the deposition rate of the diamond. Also, thermal cycling can be utilized to minimize metal inclusions as well as crystal dislocations from the grain boundaries between the diamond segments. Furthermore, a slower rate of thermal cycling and a more precise control of the temperature of the cycling may result in fewer metal inclusions and crystal dislocations. By cycling through periods of partial melting and growth, metal inclusions, contaminants, and imperfections in the crystal lattice along the grain boundary are moved out of the forming diamond body. This is partially due to the fact that a pure crystal lattice has a lower free energy than regions of crystal dislocation and metal impurities. As such, those impure regions will be preferentially melted and replaced with a more pure crystal lattice.

The metal catalyst can include any suitable metal catalyst material, depending on the desired grown crystal. Metal catalyst materials suitable for diamond synthesis can include metal catalyst powders, solid layers, or solid plates comprising any metal or alloy which includes a carbon solvent capable of promoting growth of diamond from carbon source materials. Non-limiting examples of suitable metal catalyst materials can include Fe, Ni, Co, Mn, Cr, and alloys thereof. Several common metal catalyst alloys can include Fe—Ni, e.g., INVAR alloys, Fe—Co, Ni—Mn—Co, and the like. In specific aspects, metal catalyst materials may be Fe—Ni alloys, such as Fe-35Ni, Fe31Ni-5Co, Fe-50Ni, and other INVAR alloys. Alternatively, metal catalysts can be formed by stacking layers of different materials together to produce a multi-layered metal catalyst layer or by providing regions of different materials within the catalyst layer. For example, nickel and iron plates or compacted powders can be layered to form a multi-layered Fe—Ni catalyst layer. Such a multi-layered catalyst layer can reduce costs and/or be used to control growth conditions by slowing or enhancing initial growth rates at a given temperature. In addition, the catalyst materials under diamond synthesis can include additives which control the growth rate and/or impurity levels of diamond, i.e. via suppressing carbon diffusion, prevent excess nitrogen and/or oxygen from diffusing into the diamond, or effect crystal color. Suitable additives can include Mg, Ca, Si, Mo, Zr, Ti, V, Nb, Zn, Y, W, Cu, Al, Au, Ag, Pb, B, Ge, In, Sm, and compounds of these materials with C and B.

The metal catalyst may be of any suitable spatial dimension which allows for diffusion of the carbon source into the catalyst layer and, in some cases, the maintenance of a temperature gradient. Typically, the metal catalyst can form a layer from about 1 mm to about 20 mm in thickness. However, thicknesses outside this range can be used depending on the desired growth rate, magnitude of temperature gradient, and the like.

The carbon source can be configured to provide a source of carbon for growth of a desired diamond body. Under diamond growth conditions, the carbon source may comprise a material such as graphite, amorphous carbon, diamond, diamond powder, microdiamond, nanodiamond, and combinations thereof. In one aspect of the present invention, the carbon source layer can comprise a graphite, such as a high purity graphite. Although a variety of carbon source materials can be used, graphite generally provides good crystal growth and improves homogeneity of the grown diamond. Further, low resistivity graphite may also provide a carbon source material which can also be readily converted to diamond. However, consideration should be given to the volume reduction associated with conversion of graphite to diamond. When using graphite as a carbon source, the pressure may decay as a result of volume reduction as the graphite is converted to diamond. One optional way to reduce this problem is to design a high pressure apparatus that continues to increase the pressure to compensate for the volume reduction and thus maintain a desired pressure. Despite higher manufacturing costs, using diamond powder as a carbon source may also reduce the degree of volume reduction, and thus increase the time during which optimal pressure conditions can be maintained.

The pressing force delivered to or by the high pressure apparatus may vary according to the method of delivery and the intended configuration of the resulting diamond body. As such, pressures outside the ranges disclosed herein may prove to be functional in joining diamond segments into a diamond body, and are thus considered to be included in the scope of the present invention. As such, the pressing force may be sufficient to provide ultrahigh pressures. In one aspect, the ultrahigh pressures may be from about 4 GPa to about 7 GPa. In another aspect, the ultrahigh pressures may be from about 5 GPa to about 6 GPa.

Various high pressure devices capable of delivering suitable high pressures are known to those skilled in the art, and all are considered to also be within the present scope. It is intended that high pressure apparatus include an apparatus for producing high pressures or ultrahigh pressures, and any chamber, assembly, or other enclosure for containing the diamond segments, the molten catalyst, and the carbon source. As such, an apparatus may include split die devices, girdle devices, belt devices, piston-cylinder press, and toroidal devices. In one specific aspect, the high pressure apparatus may be a split die device.

In certain high pressure growth methods, thermal energy may be applied to the diamond segments, molten catalyst, and carbon source that is sufficient to generate a high temperature. In one aspect, an electrical current can then be passed through either a graphite heating tube or graphite carbon source directly. This resistive heating of the catalyst material can be sufficient to cause melting of the metal catalyst, e.g., typically, without limitation, about 1300° C. for diamond. Under such conditions of high pressure and high temperature, the carbon source can dissolve into the molten catalyst and precipitate out in a crystalline form as diamond along the gaps between the diamond segments. Also, as described herein, the thermal energy applied to the diamond segments can be cycled in order to decrease crystal dislocations and metal inclusions along the grain boundaries.

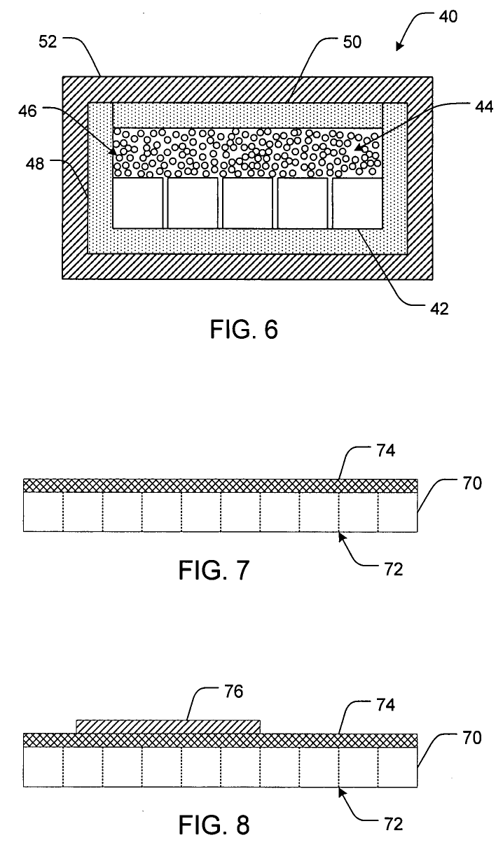

According to one aspect, FIG. 6 shows one example of a high pressure assembly 40 to be located within a high pressure apparatus (not shown) for forming a diamond body. The high pressure assembly 40 may include a plurality of diamond segments 42 arranged in close proximity within an internal space 44. In this aspect, nanodiamond particles 46 are located within the internal space 44 along with the plurality of diamond segments 42. The metal catalyst is provided by a metal catalyst cup 48 and/or a metal catalyst lid 50. The metal catalyst cup 48 and lid 50 are surrounded by a layer of graphite 52. The layer of graphite 52, functions to provide pressure transmission from the high pressure apparatus to the internal space 44, an electrical current path for heating, and additional carbon source material for growth within the molten catalyst. As high pressure and possibly heat are applied to the high pressure assembly 40, at least a portion of the metal catalyst melts to form the molten catalyst and the carbon source melts. Diamond growth occurs in the gaps between the diamond segments 42 as described herein, thus forming a diamond body.

As has been described, the diamond bodies created by the methods of the present invention can be of numerous configurations, sizes, thicknesses, and shapes. In one aspect, the diamond body can be a sheet of diamond. In one aspect, the sheet of diamond may be essentially lattice matched. The diamond body may include a sheet of diamond having a thickness of at least 0.1 mm and a width of at least 1 mm. The sheet of diamond may be of various thicknesses. In one aspect, the sheet of diamond may have a thickness of at least 0.5 mm. In another aspect, the sheet of diamond may have a thickness of at least 1 mm. In yet another aspect, the sheet of diamond may have a thickness of at least 2.5 mm. In another aspect, the sheet of diamond may have a thickness of at least 5 mm. In yet another aspect, the sheet of diamond may have a thickness of at least 10 mm. In a further aspect, the sheet of diamond may have a thickness of at least 20 mm. Also, various widths of sheets of diamond are contemplated. In one aspect, the sheet of diamond may have a width of at least 5 mm. In another aspect, the sheet of diamond may have a width of at least 10 mm. In one aspect, the sheet of diamond may have a width of at least 50 mm. In yet another aspect, the sheet of diamond may have a width of at least 100 mm. In addition to width and thickness, various lengths are contemplated for the sheet of diamond. Length may be defined as a linear measurement that is perpendicular to the width of the diamond sheet. In one aspect, the sheet of diamond may have a length of at least 5 mm. In another aspect, the sheet of diamond may have a length of at least 10 mm. In one aspect, the sheet of diamond may have a length of at least 50 mm. In another aspect, the sheet of diamond may have a length of at least 100 mm. It is also contemplated that the diamond sheet need not be rectangular or even symmetrical, but that the length and width measurements described herein may correspond to approximations of the size of various non-rectangular bodies, such as, without limitation, circular, oval, pyramidal, or irregularly shaped sheets of diamond or other diamond bodies. Additionally, the diamond sheet may be formed on a substrate. In one aspect, the substrate is a temporary substrate to be removed after construction of the sheet of diamond or other diamond body. In another aspect, the substrate or at least a portion thereof can be a permanent addition to the sheet of diamond or diamond body.

As has been described, the substantially single crystal diamond body may be used in the construction of various diamond semiconductor devices. For example, in one aspect a semiconductive single crystal diamond device is provided including a substantially single crystal diamond body made as is described herein, a homoepitaxial single crystal diamond layer coated on the single crystal diamond body, and a dopant disposed within the homoepitaxial single crystal diamond layer to form a semiconductive single crystal diamond layer. FIG. 7 shows an example of a diamond semiconductor device having a substantially single crystal diamond body 70. In this aspect, the substantially single crystal diamond body 70 is formed from a plurality of cubic diamond segments that have been fused along their edges 72 to form a single structure. A doped homoepitaxial single crystal diamond layer 74 is deposited onto the substantially single crystal diamond body 70 to form a diamond semiconductor.

The homoepitaxial single crystal diamond layer may be deposited by various means known to one of ordinary skill in the art. In one aspect, such deposition may be accomplished by vapor deposition processes. Any number of known vapor deposition techniques may be used to form the homoepitaxial single crystal diamond layer, or the boron nitride layers discussed further herein. The most common vapor deposition techniques include chemical vapor deposition (CVD) and physical vapor deposition (PVD), although any similar method can be used if similar properties and results are obtained. In one aspect, CVD techniques such as hot filament, microwave plasma, oxyacetylene flame, rf-CVD, laser CVD (LCVD), metal-organic CVD (MOCVD), laser ablation, conformal diamond coating processes, and direct current arc techniques may be utilized. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, as well as those used for boron nitride layers, are well known to those skilled in the art.

In one specific aspect, the diamond layer may be conformally deposited to potentially increase the homoepitaxial nature of the deposition process. Conformal diamond coating processes can provide a number of advantages over conventional diamond film processes. A growth surface can be pretreated under diamond growth conditions in the absence of a bias to form a carbon film. The diamond growth conditions can be conditions which are conventional CVD deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

Following formation of the thin carbon film, the growth surface may then be subjected to diamond growth conditions to form the amorphous diamond layer. The diamond growth conditions may be those conditions which are commonly used in traditional CVD diamond growth. However, unlike conventional diamond film growth, the diamond film produced using the above pretreatment steps results in a conformal diamond film that typically begins growth substantially over the entire growth surface with substantially no incubation time. Such simultaneous initiation of growth of the diamond layer may thus further reduce the likelihood of grand boundaries and crystal lattice dislocations forming in the growing diamond layer.

Various dopants may be introduced into the homoepitaxial single crystal diamond layer to form the semiconductive diamond device. It should be noted that any dopant capable of facilitating semiconductive properties into the diamond layer would be considered to be within the present scope, including those dopants that provide n-type or p-type semiconductive properties to the diamond material. In one aspect, non-limiting examples of dopants may include N, P, As, Sb, Bi, B, Al, Ga, In, and combinations thereof. In one specific example, however, the dopant may include B. In another specific example the dopant may include N. In yet another specific example the dopant may include P.

Various methods of doping the homoepitaxial single crystal diamond layer are contemplated, and may vary depending on the technique used to deposit the diamond layer. Accordingly, any such method of introducing a dopant into a diamond material would be considered to be within the present scope. In one aspect, for example, the dopant may be introduced in specific amounts into the chamber during vapor deposition. In this way, specific proportions of dopants are incorporated into the crystal lattice of the forming diamond layer. Such doping techniques are considered to be within the knowledge of one of ordinary skill in the art.

Additional doped layers may be associated with the doped homoepitaxial single crystal diamond layer to construct specific semiconductor devices. Such additional layers may include diamond and non-diamond semiconducting materials. In some aspects, such a specific semiconductor device may be one of a variety of p-n junctions. In one aspect, for example, cubic boron nitride materials may be utilized. Accordingly, in one aspect exemplified in FIG. 8, a semiconductor device is provided that includes a substantially single crystal diamond body 70 made as is described herein. A homoepitaxial single crystal diamond layer 74 is coated on the single crystal diamond body, and a first dopant of either B or Al is disposed within the homoepitaxial single crystal diamond layer 74 to form a semiconductive single crystal diamond layer. A single crystal cubic boron nitride layer 76 is disposed adjacent to the homoepitaxial single crystal diamond layer 74, and a second dopant of N, P, or As is disposed within the cubic boron nitride layer 76 to form a semiconductive single crystal cubic boron nitride layer. In one specific aspect, the first dopant may be B. In another specific aspect, the second dopant may be N. Furthermore, as has been described, disposed adjacent to may include situations where the layers are on top of one another, next to one another, within one another, etc. Additionally, although the layers are electrically coupled, they may be in physical contact or they may be separated by a dielectric material (not shown). As such, it should be noted that the placement of the cubic boron nitride layer 76 with respect to the homoepitaxial single crystal diamond layer 74 as shown in FIG. 8 is for convenience, and should not be seen as limiting.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of making a semiconductive single crystal diamond layer, comprising:
placing a plurality of diamond segments in close proximity under high pressure in association with a molten catalyst and a carbon source, the diamond segments being arranged in a single crystal orientation;
maintaining the plurality of diamond segments under high pressure in the molten catalyst until the plurality of diamond segments have joined together with diamond to diamond bonds to form a substantially single crystal diamond body;
depositing a homoepitaxial single crystal diamond layer on the single crystal diamond body; and
introducing a dopant into the homoepitaxial single crystal diamond layer to form the semiconductive single crystal diamond layer.

2. The method of claim 1, wherein the molten catalyst includes a metal catalyst selected from the group consisting of Cr, Mn, Fe, Co, Ni, and combinations and alloys thereof.

3. The method of claim 3, wherein the molten catalyst includes an Fe—Ni alloy.

4. The method of claim 1, wherein the plurality of diamond segments are arranged into a pattern prior to being placed under high pressure in a molten catalyst.

5. The method of claim 4, wherein the plurality of diamond segments are affixed to a support substrate prior to being placed under high pressure in a molten catalyst.

6. The method of claim 5, wherein the plurality of diamond segments are affixed to the support substrate by electroplating.

7. The method of claim 5, wherein the plurality of diamond segments are affixed to the support substrate by a CVD diamond film.

8. The method of claim 1, wherein the carbon source includes a member selected from the group consisting of graphite, diamond, diamond powder, nanodiamond, microdiamond, and combinations thereof.

9. The method of claim 1, wherein the diamond segments have a cubic shape.

10. The method of claim 9, wherein the cubic shape is obtained without post-growth processing.

11. The method of claim 1, wherein introducing a dopant occurs during deposition of the homoepitaxial single crystal diamond layer.

12. The method of claim 1, wherein the dopant includes a member selected from the group consisting of N, P, As, Sb, Bi, B, Al, Ga, In, and combinations thereof.

13. The method of claim 1, wherein the dopant is B.

14. The method of claim 1, wherein the dopant is N.

15. The method of claim 1, wherein the dopant is P.

16. A semiconductive single crystal diamond device, comprising:
a substantially single crystal diamond body made as in claim 1;
a homoepitaxial single crystal diamond layer coated on the single crystal diamond body; and
a dopant disposed within the homoepitaxial single crystal diamond layer to form a semiconductive single crystal diamond layer.

17. The device of claim 16, wherein the dopant includes a member selected from the group consisting of N, P, As, Sb, Bi, B, Al, Ga, In, and combinations thereof.

18. The device of claim 16, wherein the dopant is B.

19. The device of claim 16, wherein the dopant is N.

20. The device of claim 16, wherein the dopant is P.

21. The device of claim 16, wherein the single crystal diamond body is formed from diamond segments having a cubic shape.

22. A semiconductor device, comprising:
a substantially single crystal diamond body made as in claim 1;
a homoepitaxial single crystal diamond layer coated on the single crystal diamond body;
a first dopant disposed within the homoepitaxial single crystal diamond layer to form a semiconductive single crystal diamond layer, the first dopant being either B or Al;
a single crystal cubic boron nitride layer disposed adjacent to the homoepitaxial single crystal diamond layer; and
a second dopant disposed within the cubic boron nitride layer to form a semiconductive single crystal cubic boron nitride layer, the second dopant being N, P, or As.

23. The device of claim 22, wherein the first dopant is B.

24. The device of claim 22, wherein the second dopant is N.
